(19) United States
(12) Patent Application Publication
(10) Pub. No.: US 2016/0351317 A1
(43) Pub. Date: Dec. 1, 2016

(54) HYBRID INDUCTOR DEVICE

(71) Applicant: SAMSUNG ELECTRO-MECHANICS CO., LTD., Suwon-si (KR)

(72) Inventor: Seong Jong CHEON, Suwon-si (KR)

(73) Assignee: SAMSUNG ELECTRO-MECHANICS CO., LTD, Suwon-si (KR)

(21) Appl. No.: 15/050,568

(22) Filed: Feb. 23, 2016

(30) Foreign Application Priority Data
Jun. 1, 2015 (KR) 10-2015-0077406

(51) Int. Cl. H01F 27/28; H03H 7/38; H03H 7/46

(52) U.S. Cl. CPC H01F 27/2804; H03H 7/463; H03H 7/38; H01F 2027/2809

(57) ABSTRACT

A hybrid inductor includes a board-type inductor having a conductive pattern, configured to generate an inductance, disposed on a board; and at least one chip-type inductor disposed on a surface of the board, wherein one end of the at least one chip-type inductor is electrically connected to the conductive pattern.

### CROSS-REFERENCE TO RELATED APPLICATION

This application claims the benefit under 35 USC 119(a) of Korean Patent Application No. 10-2015-0077406 filed on Jun. 1, 2015, with the Korean Intellectual Property Office, the entire disclosure of which is incorporated herein by reference for all purposes.

### BACKGROUND

1. Field

The following description relates to a hybrid inductor device capable of improving a Q value.

2. Description of Related Art

An inductor, a passive device configuring an electronic circuit together with a resistor and a capacitor, is used in various systems and components such as low-noise amplifiers, mixers, voltage control oscillators, matching coils, and the like.

As electronic devices are miniaturized, the miniaturization of electronic device modules mounted in the electronic devices has been desired. However, in a case of inductors, as the size of inductors has decreased, inductor Q values have also decreased. In addition, according to previous techniques, since in most cases, only a single inductor is used in electronic device modules, it may be difficult to accurately implement a desired level of inductance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a hybrid inductor has a small size and a high Q value, capable of providing an accurate level of inductance 0. The hybrid inductor device includes a board-type inductor having a conductive pattern, configured to generate a first inductance, disposed in or on a board, and at least one chip-type inductor disposed on a surface of the board, wherein the at least one chip-type inductor is electrically connected to the conductive pattern and configured to generate a combined inductance with the first inductance.

The conductive pattern may be a coil structure. The conductive pattern may have a helical structure, a spiral structure, a single loop structure, a meandering structure, or a solenoid structure, or any combination thereof.

The board-type inductor may further include a plurality of insulating layers, respective conductive patterns disposed on the plurality of insulating layers, and respective conductive vias extending through the plurality of insulating layers and electrically connecting the respective conductive patterns. The board-type inductor may have a lower inductance than an inductance of the chip-type inductor.

The board-type inductor may further include a connection pad disposed on the surface of the board, and may be connected to an end of the chip-type inductor distinguished from an end of the chip-type inductor connected to the conductive pattern.

The board may be a main board for an electronic device and may include at least one electronic component mounted on the main board.

In another general aspect, a hybrid inductor device includes a first inductor, and a second inductor including a conductive pattern having a coil structure, wherein the second inductor is electrically connected to the first inductor and configured to generate a combined inductance.

The coil structure may include a helical structure, a spiral structure, a single loop structure, a meandering structure, or a solenoid structure, or any combination thereof.

The first inductor may include a conductive coil structure disposed in a ceramic body. The conductive pattern may be disposed on an insulating layer.

The second inductor may include a plurality of insulating layers configured to generate an inductance, wherein the plurality of insulating layers are stacked.

In another general aspect, a hybrid inductor device includes a main board, one or more electronic components mounted on the main board, a first inductor mounted on the main board, and a second inductor having a conductive pattern disposed on the main board and connected to the first inductor.

The one or more electronic components may include at least one duplexer and at least one antenna switch, and the first inductor may be disposed between the duplexer and the antenna switch, so as to be electrically connected to the duplexer and the antenna switch.

The first and second inductors may be configured to impedance match the duplexer or the antenna switch.

The second inductor may be disposed on the main board, below a mounting region of the one or more electronic components or the first inductor.

Other features and aspects will be apparent from the following detailed description, the drawings, and the claims.

### BRIEF DESCRIPTION OF DRAWINGS

FIG. 1 is a perspective view schematically illustrating a hybrid inductor device according to one or more embodiments;

FIG. 2 is an exploded perspective view schematically illustrating a chip-type inductor of the hybrid inductor device illustrated in FIG. 1;

FIG. 3 is a cross-sectional view schematically illustrating a board-type inductor device of the hybrid inductor illustrated in FIG. 1;

FIG. 4 is a perspective view schematically illustrating a hybrid inductor device according to one or more embodiments;

FIG. 5 is a perspective view schematically illustrating a hybrid inductor device according to one or more embodiments;

FIG. 6 is a perspective view schematically illustrating hybrid inductor device having a hybrid inductor according to one or more embodiments; and

FIG. 7 is a plan view of FIG. 6.

Throughout the drawings and the detailed description, the same reference numerals may refer to the same or like elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, after an understanding of the following description, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order, after an understanding of the present disclosure. Also, descriptions of functions and constructions that understood from previous disclosures in the art may be omitted from subsequent disclosures for increased clarity and conciseness.

The features described herein may be embodied in different forms, and are not to be construed as being limited to the examples described herein. Rather, the examples described herein have been provided so that this disclosure will be thorough and complete, and will convey a scope of the disclosure to one of ordinary skill in the art.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Unless indicated otherwise, any statement that a first layer is “on” a second layer or a substrate is to be interpreted as covering both a case where the first layer directly contacts the second layer or the substrate, and a case where one or more other layers are disposed between the first layer and the second layer or the substrate.

Any words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

The terminology used herein is for describing particular embodiments only and is not intended to be limiting of the present disclosure. As used herein, the singular forms “a,” “an,” and “the” are intended to include the plural forms as well, unless the context clearly indicates otherwise. It will be further understood that the terms “comprises,” and/or “comprising” when used herein, specify the presence of stated features, integers, steps, operations, members, elements, and/or groups thereof, but do not preclude the presence or addition of one or more other features, integers, steps, operations, members, elements, and/or groups thereof.

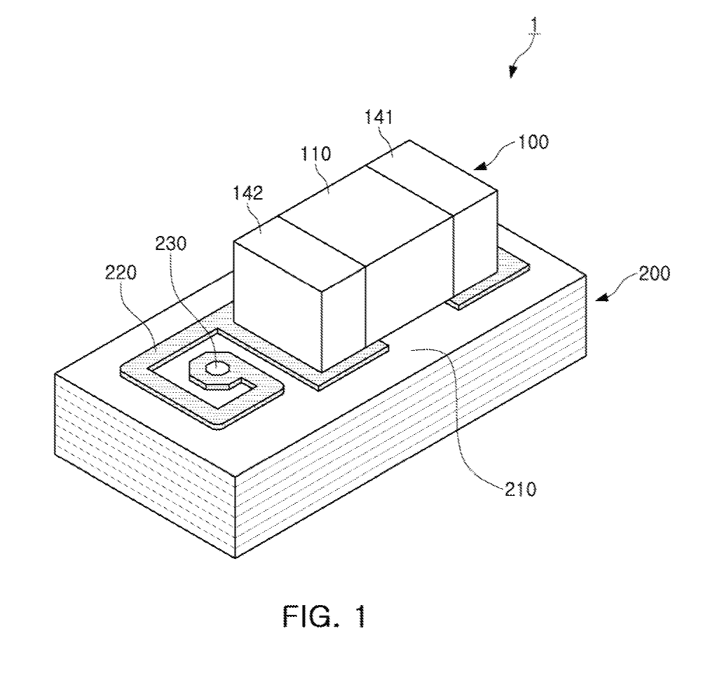

Referring to FIGS. 1 through 3, a hybrid inductor device 1 according to one or more embodiments includes a chip-type inductor 100 (hereinafter, referred to as a first inductor) and a board-type inductor 200 (hereinafter, referred to as a second inductor).

The first inductor 100 includes a chip inductor or surface mounting device (SMD) inductor, for example. Therefore, the first inductor 100 includes a ceramic body 110 and conductive coil structures formed in the ceramic body 110, wherein the conductive coil structures include conductive patterns 120 stacked together and a plurality of conductive vias 130 connecting multiple conductive patterns to each other in parallel and/or in series to complete the coil structures.

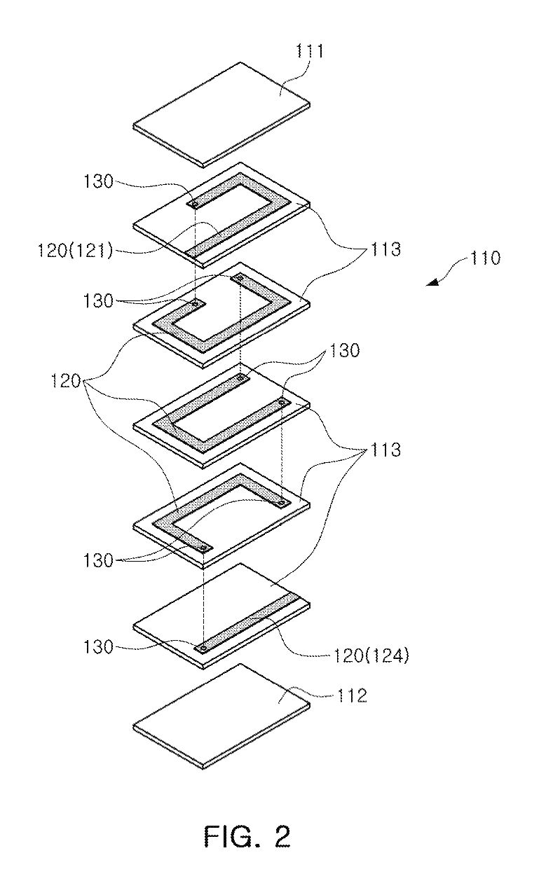

In an embodiment, upper and lower cover layers 111 and 112 are disposed on upper and lower surfaces of the ceramic body 110 in order to protect the printed conductive patterns in the ceramic body 110. The upper and lower cover layers 111 and 112 include a single ceramic layer or a plurality of layers of ceramic sheets respectively stacked in a thickness direction. In an embodiment, the ceramic body 110 includes a plurality of ceramic layers 113, formed of ceramic sheets, sintered in a thickness direction. The shape and dimensions of the ceramic body 110 and the number of stacked ceramic layers 113 may be varied and are not limited to those illustrated in FIG. 2, for example.

As only an example, the conductive pattern 120 may be formed by printing a conductive paste containing a conductive metal on each of the ceramic layers 113 to a predetermined thickness. For example, the conductive pattern 120 may be formed of a material containing a conductor, such as silver (Ag) or copper (Cu), or an alloy thereof, but the material of the conductive pattern 120 is not limited thereto and may vary.

Further, a total number of stacked ceramic layers 113 on which the conductive pattern 120 is formed may be variously determined, depending on an embodiment, e.g., in consideration of designed level of inductance or electrical properties to be desired. For example, the total number of stacked ceramic layers 113 and the conductive pattern 120 may be varied according to the desired inductance.

Further, at least two of the conductive patterns 120 include first and second connection patterns 121 and 124 extending to both end surfaces of the ceramic body 110, respectively. In an embodiment, first and second connection patterns 121 and 124 are electrically connected to first and second external electrodes 141 and 142 disposed on both end surfaces of the ceramic body 110, for example.

Although a case in which the first and second connection patterns 121 and 124 are disposed on upper and lower portions of the ceramic body 110 is described by way of example, the positions of the first and second connection patterns 121 and 124 are not limited thereto. That is, the positions of the first and second connection patterns may be varied, depending on embodiment. For example, the first and second connection patterns may be arranged in the center of the stacked ceramic layers.

In an embodiment, the conductive via 130 penetrates through each of the ceramic layers 113, and electrically connects the stacked conductive patterns 120 to each other, for example, thereby completing a coil structure of the first inductor.

The case in which the conductive patterns 120 of the first inductor 100 are stacked and disposed in a thickness direction of the first inductor 110 is described by way of example. However, a stacking direction of the conductive patterns 120 is not limited thereto, but the conductive patterns 120 may be stacked in a length direction of the first inductor 100. Alternatively, the conductive pattern 120 may be formed on a single layer. Further, the conductive pattern may be variously changed, depending on embodiment. For example, a conductor wire or rectangular wire may be disposed in the ceramic body 110 instead of the pattern, depending on embodiment.

In one or more embodiments, the second inductor 200 includes a board-type inductor 200 in which conductive patterns 220 are formed having a coil structure disposed on a board 210. For example, the conductive patterns 220 having the coil structure are conductive patterns 220 configured to have inductance in the board 210. Therefore, the second inductor 200 may be a monolayer board 210 in which the conductive patterns 220 is formed on a single insulating layer 211, or a multilayer circuit board formed by stacking a plurality of insulating layers 211 on which the conductive patterns 220 are formed, depending on embodiment.

Here, the multilayer circuit board may be a general printed circuit board (PCB). However, the multilayer circuit board is not limited thereto, but may be formed as a flexible board such as a film board. Further, various boards such as a ceramic board, a glass board, or the like, may be used as long as such conductive patterns 220 are formed thereon.

For example, the board 210 according to one or more embodiments, includes a multilayer board 210 in which at least three layers of the conductive patterns 220 are stacked.

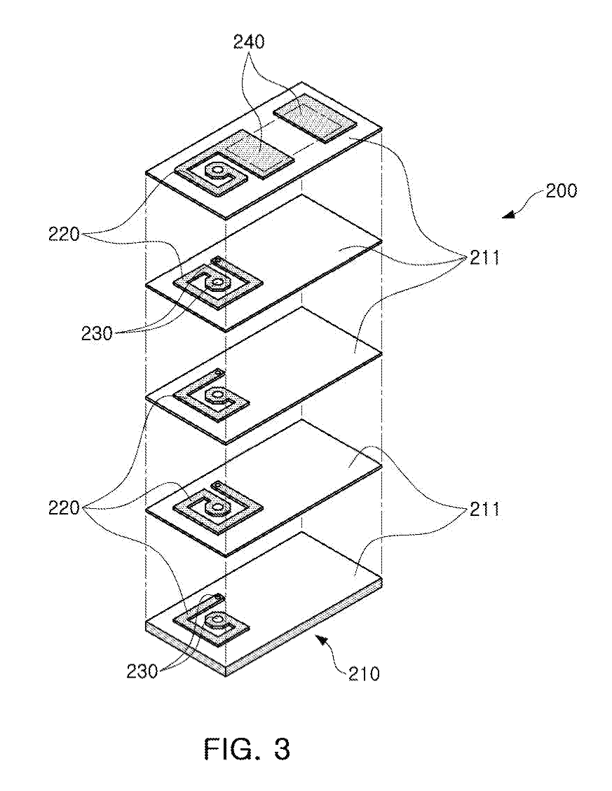

Referring to FIG. 3, the conductive patterns 220 are formed on any one portion of the insulating layer 211. Therefore, in an embodiment, a wiring pattern for transferring electrical signals is formed on another region thereof on which the conductive patterns 220 are not formed. However, the conductive patterns 220 are not limited thereto, but the conductive pattern may also be formed on the entire insulating layer, depending on embodiment.

Further, the conductive patterns 220 for the coil structure may be formed on only some of insulating layers 211 forming the board 210. In this case, a wiring pattern for transferring electrical signals is formed on the other insulating layers 211 on which the conductive patterns 220 for the coil structure is not formed. However, the configuration of the conductive pattern is not limited thereto, but the conductive pattern may be varied, depending on embodiment. For example, the conductive pattern may be formed using all of the insulating layers 211, noting that alternative embodiments are available.

The wiring pattern may be a pattern electrically connecting the conductive patterns 220 externally. Further, in a case in which the board 210 is used as a main board, the wiring pattern may be a pattern for configuring a circuit of the main board.

A plurality of coil turns forming the coil structure of the second inductor 200 is dispersed among the conductive patterns 220 on a plurality of layers, respectively. Therefore, at least one coil turn is formed in the conductive pattern on each of one or more, or all of the layers 211. Each of the conductive pattern may be electrically connected to each other by a connective conductor 230 penetrating through each insulating layer 211, for example. That is, as an example, the conductive patterns 220 completes a single continuous coil structure through the connective conductor 230.

The conductive patterns 220 according to one or more embodiments may be formed to have a helical structure. However, the structure of the conductive patterns 220 is not limited thereto; the conductive patterns 220 may have any one of various coil structures such as a spiral structure, a single loop structure, a meandering structure, a solenoid structure, or alternative structure, or any combination thereof.

A connection pad 240 on which the first inductor 100 is mounted is disposed on an upper surface of the multilayer board 210. For example, the first inductor 100 connects to the connection pad 240 through a conductive member, such as solder to thereby electrically connect to the second inductor 200.

In addition, depending on embodiment, a pad connected to a main board on which the hybrid inductor device 1 is mounted or pin shaped connection terminals are formed on a lower surface of the second inductor 200. In this case, each of the connection terminals electrically connects the first and second inductors to each other.

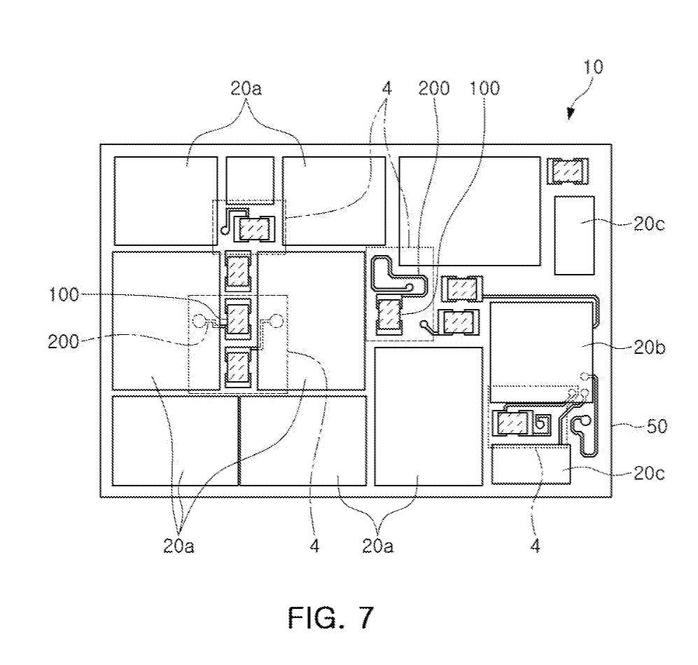

Further, the board 210 constituting the second inductor 200 may be formed as the main board. For example, as illustrated in FIG. 7, in a case in which the second inductor 200 is configured not as a separate board but as a coil structure using conductive patterns 220 and a connection pad 240 on a main board on which at least one other electronic component is mounted, the board 210 of the second inductor 200 is utilized as the main board. In FIG. 7, a main board embodiment with multiple hybrid inductors and other electronic components, or the electronic device embodiment that includes such a main board, may be considered a hybrid inductor device.

In the hybrid inductor 1 according to one or more embodiments as described above, the first inductor 100 is chip-type inductor and the second inductor 200 is a board-type inductor, and the first and second inductors are coupled to each other, thereby completing a single hybrid inductor. In addition, in the hybrid inductor 1 according to one or more embodiments, chip inductors having various levels of inductance may be used as the first inductor 100 and selectively mounted in the second inductor 200 as needed. For example, a first inductor 100 having the desired level of inductance may be selected from chip inductors having different levels of inductance, for example 5.6 nH, 6.1 nH, 6.8 nH, 7.5 nH, or 9.1 nH. desired The second inductor 200 provides a more precise level of inductance compared to precision level of inductance of the first inductor 100. For example, the second inductor 200 provides a level of inductance that may not be provided only by the first inductor 100.

For example, in order to implement a level of inductance of 8.2 nH, where a first inductor is selected or formed having a level of inductance of 7.5 nH, the second inductor 200 may be configured so as to add 0.7 nH, a deficient level of inductance between the desired 8.2 nH and the 7.5 nH inductance of the first inductor. Thus, the level of inductance of 8.2 nH may be accurately implemented by connecting the first inductor with the second inductor by the hybrid inductor device.

In this case where the desired inductance is 8.2 nH, using only the first inductor 100 without the second inductor 200, where the available first inductors having the closest level of inductance are 7.5 nH or 9.1 nH, results in is a difference between the desired level of inductance and the level of inductance that may be actually provided. This difference may create difficulty in optimizing a circuit or module.

Further, in order to precisely match a level of inductance using only a single inductor, there is a need to separately manufacture the particular inductor having the corresponding level of inductance. However, since a deficient level of inductance of the first inductor 100 is supplemented using the second inductor 200, a level of inductance which is hard to be implemented by only a single inductor may be provided by the hybrid inductor device, according to one or more embodiments. Therefore, an optimized module (or circuit) may be easily designed and manufactured.

In a case in which a deficient level of inductance of the first inductor 100 is supplemented using the second inductor 200 as described above, the second inductor 200 may have a lower level of inductance than that of the first inductor. However, the second inductor is not limited thereto, but if desired, the second inductor 200 may be formed to have a higher level of inductance, depending on embodiment.

Further, in the case of the chip-type inductor 100, as a size thereof is increased, a Q value tends to increase. Therefore, in a case of decreasing the size of the inductor, the Q value decreases. However, when the chip-type inductor 100 and the board-type inductor 200 are combined with each other to become the hybrid inductor device, as in one or more embodiments, an overall Q value is improved as compared to a case using only the chip-type inductor 100. The inductor embedded in the board 210 has a greater Q value than the first inductor 100, therefore, the overall Q value is increased.

Further, in a case of a chip-type inductor 100 having a high level of inductance, a self resonance frequency (SRF) is low, thus stability of the inductance may be deteriorated. However, in the case of the hybrid inductor device 1 according to one or more embodiments, the SRF of the chip-type inductor 100 and the board-type inductor 200 is relatively increased as compared to a single chip-type inductor 100, therefore, stability of the inductance may be ensured.

Further, in the hybrid inductor 1 according to one or more embodiments, a change in a level of inductance due on a change in frequency is significantly decreased. For example, in order to provide a level of inductance of 10 nH, a chip-type inductor 100 having a level of inductance of 4.3 nH and a board-type inductor 200 having a level of inductance of 5.7 nH may be combined with each other, thereby implementing a hybrid inductor device 1 according to one or more embodiments. Here, when a frequency band of the hybrid inductor device 1 changes from 1 GHz to 2 GHz, the level of inductance of the hybrid inductor device 1 changes by 0.65 nH. Conversely, in a case of changing a frequency band as described above in a single chip-type inductor having a level of inductance of 10 nH, the level of inductance changes by 1.18 nH. Therefore, the hybrid inductor device 1 according to one or more embodiments may have high stability against a change in frequency band.

The hybrid inductor and devices according to the present disclosure are not limited to the above-mentioned embodiments but may be variously modified, depending on embodiments.

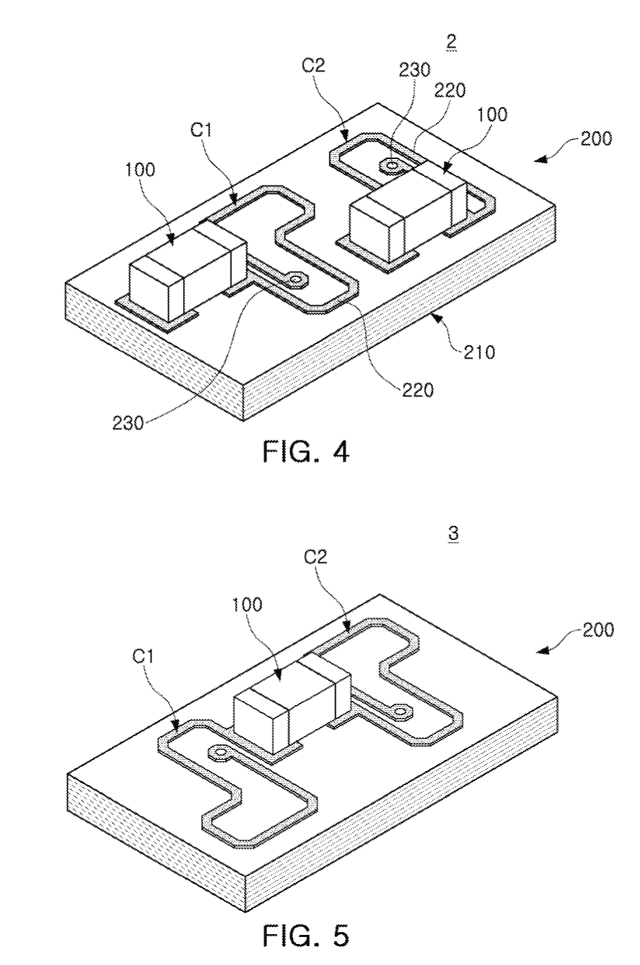

FIG. 4 is a perspective view schematically illustrating a hybrid inductor device according to another embodiment.

Referring to FIG. 4, a hybrid inductor device 2 according to one or more embodiments includes two chip-type inductors 100, and at least two coil structures C1 and C2 formed by conductive patterns 220 on a board-type inductor 200.

For example, the chip-type inductors 100 are electrically connected to the coil structures C1 and C2 formed on the board-type inductor 200, respectively. Further, each of the coil structures C1 and C2 may be electrically insulated from each other or electrically connected to each other. For example, one end of two coil structures C1 and C2 may be connected to each other. In this case, two chip-type inductors 100 and two coil structures C1 and C2 may all be connected to each other in series. However, a connection structure of the hybrid inductor device 2 is not limited thereto. That is, as desired, the connection structure may be variously changed, depending on embodiment. For example, both ends of two coil structures C1 and C2 may be electrically connected to each other to form a parallel structure, or two chip-type inductors 100 may be connected to each other in parallel.

Further, as described above, the coil structures C1 and C2 of the board-type inductor 200 may be formed to have a helical structure, but are not limited thereto. That is, the coil structures C1 and C2 may have various coil structures such as a spiral structure, a single loop structure, a meandering structure, a solenoid structure, or an alternate structure, or any combination thereof.

Although a case in which the hybrid inductor device 2 includes two chip-type inductors 100 and one board-type inductor 200 is described by way of example, the hybrid inductor device 2 is not limited thereto. That is, the hybrid inductor device 2 may be configured to include more chip-type inductors 100 and coil structures of a board-type inductor 200.

FIG. 5 is a perspective view schematically illustrating a hybrid inductor device according to another embodiment.

Referring to FIG. 5, in a hybrid inductor device 2 according to one or more embodiments, coil structures C1 and C2 are disposed at both ends of a single chip-type inductor 100, respectively. That is, the single chip-type inductors 100 is electrically connected to two coil structures C1 and C2 formed on a board-type inductor 200. The coil structures C1 and C2 are disposed at both ends of the chip-type inductor 100, and are formed in a helical structure. However, the shape of the coil structures C1 and C2 is not limited thereto, and the two coil structures C1 and C2 may be formed to have different shapes from each other. The shapes of the coil structures may be changed as desired, depending on embodiment. For example, a coil structure having a spiral shape may be formed at one end of the chip-type inductor 100, and a coil structure having a single loop shape may be formed at the other end of the chip-type inductor 100.

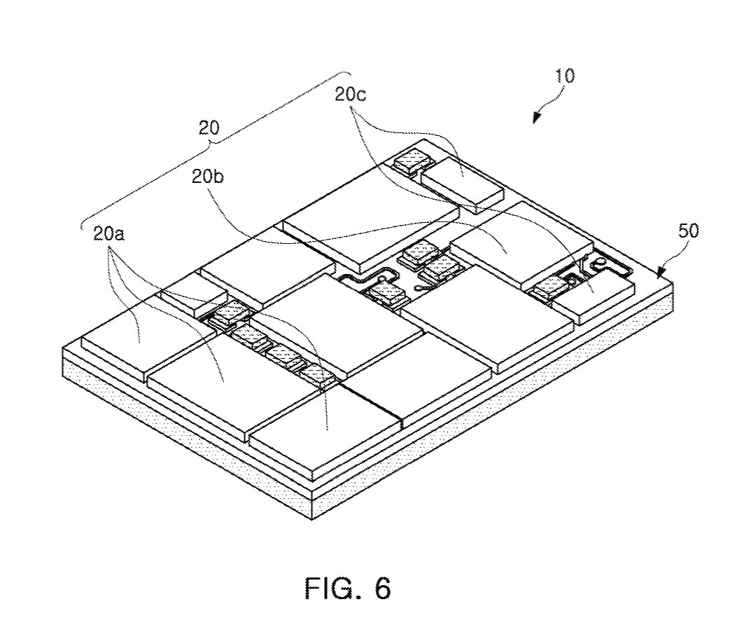

FIG. 6 is a perspective view schematically illustrating a hybrid inductor device having a hybrid inductor according to one or more embodiments, and FIG. 7 is a planar view of FIG. 6.

Referring to FIGS. 6 and 7, they hybrid inductor device may be an electronic device module 10 according one or more embodiments, including a number of electronic components mounted on a main board. The electronic device module 10 according to one or more embodiments may be a radio frequency (RF) module. Here, the RF module may be a module dividing high frequency signals received in an antenna of a mobile phone embodiment into transmission signals and reception signals according to the communications band to transfer the divided signals. That is, the electronic device module 10 according to one or more embodiments is a module mounted in the mobile phone embodiment to serve to transmit/receive wireless signals. Therefore, in this example, the electronic devices 20 include at least one antenna switch 20b and a plurality of duplexers 20a, and include various devices such as a band-pass filter (BPF) 20c, a power amplifier (not illustrated), and other components. In addition, although not illustrated, the electronic devices 20 may be sealed by a molding resin to thereby be packaged.

A main board 50 is a multilayer board, such as a general printed circuit board (PCB). However, the main board 50 is not limited thereto, for instance, a flexible board such as a film board may be used. Further, various boards such as a ceramic board, or a glass board, may be used as long as a conductive pattern is formed thereon.

Further, the electronic device module 10 according to one or more embodiments include at least one hybrid inductor 4 (See FIG. 7). The hybrid inductor 4 may be used for antenna matching or impedance matching between the duplexer 20a and the antenna switch 20b.

In the hybrid inductor 4, a second inductor 200, a board-type inductor, is disposed on the main board 50, and a first inductor 100, a chip-type inductor, is mounted on the main board 50 to thereby be electrically connected to the second inductor 200. Therefore, the hybrid inductor 4 shown in FIGS. 6 and 7 uses the main board 50 to connect the first inductor 100 with the second conductor 200 without a separate board 210 (as in the embodiment shown in FIG. 1).

For antenna matching, generally, a high inductance inductor having a level of inductance of 8 to 13 nH may be used. However, since in commercialized components according to the related art, having high inductance, an inductance interval (for example, 6.8 nH, 7.5 nH, and 9.1 nH) is wide, it may be difficult to implement a precise level of inductance (for example, 8.2 nH) optimized for a circuit.

Further, since the electronic device module 10 according to one or more embodiments is a component capable of being mounted in the mobile phone embodiment, the electronic device module 10 may be desired to be manufactured to have a significantly small size (for example, 6.5 mm×4.5 mm). Therefore, a high inductance inductor, may be difficult to mount in a small sized electronic device module 10 due to the large size of the inductor.

Conversely, the hybrid inductor 4 according to one or more embodiments provides a level of inductance (for example, 8.2 nH) that may be achieved by the first inductor 100 using the second inductor 200 disposed on the main board 50. Therefore, a precise level of inductance and a high Q value may be achieved, and a circuit may be optimized.

Further, since the desired level of inductance is determined by the first and second inductors 100 and 200, a low inductance, small, chip-type inductor may be used as the first inductor 100. In addition, the second inductor 200 is formed on the main board 50, and the first inductor 100 and other electronic devices 20 are mounted on a surface of the main board 50. In this case, the second inductor 200 may be disposed in a form of a pattern below a mounting region on which the electronic device 20 or the first inductor 100 is mounted. Therefore, a spacing interval between the electronic devices 20 may be decreased, and thus, a size of the electronic device module 10 may be significantly reduced.

Although a case in which five hybrid inductors 4 are disposed in the electronic device module 10 is illustrated in FIG. 7 by way of example, the electronic device module 10 is schematically illustrated for convenience of explanation. The number of hybrid inductors is not limited thereto. Therefore, a larger or smaller number of hybrid inductors may be disposed at various positions as desired, depending on embodiment.

As set forth above, in a hybrid inductor device according to one or more embodiments, because the deficient level of inductance of the first inductor is supplemented using the second inductor, a level of inductance difficult to implement using only a single inductor is provided, so that the optimized module, for example, may be easily designed and manufactured.

Further, since the hybrid inductor has a relatively high SFR as compared to a single chip-type inductor, stability of inductance may be ensured.

As a non-exhaustive example only, the hybrid inductor device as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device capable of wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A hybrid inductor device comprising:
a board-type inductor comprising:
a conductive pattern, configured to generate a first inductance, disposed in or on a board; and
at least one chip-type inductor disposed on a surface of the board, wherein the at least one chip-type inductor is electrically connected to the conductive pattern and configured to generate a combined inductance with the first inductance.

2. The hybrid inductor device of claim 1, wherein the conductive pattern is a coil structure.

3. The hybrid inductor device of claim 1, wherein the conductive pattern comprises a helical structure, a spiral structure, a single loop structure, a meandering structure, or a solenoid structure, or any combination thereof.

4. The hybrid inductor device of claim 1, wherein the board-type inductor further comprises:
a plurality of insulating layers;
respective conductive patterns disposed on the plurality of insulating layers; and
respective conductive vias extending through the plurality of insulating layers and electrically connecting the respective conductive patterns.

5. The hybrid inductor device of claim 1, wherein the board-type inductor has a lower inductance than an inductance of the chip-type inductor.

6. The hybrid inductor device of claim 1, wherein the board-type inductor further comprises a connection pad disposed on the surface of the board, and connected to an end of the chip-type inductor distinguished from an end of the chip-type inductor connected to the conductive pattern.

7. The hybrid inductor device of claim 2, wherein the conductive pattern is connected to an end of the chip-type inductor distinguished from an end of the chip-type inductor connected to the conductive pattern.

8. The hybrid inductor device of claim 1, wherein the board is a main board for an electronic device and includes at least one electronic component mounted on the main board.

9. A hybrid inductor device comprising:
a first inductor; and
a second inductor comprising a conductive pattern having a coil structure, wherein the second inductor is electrically connected to the first inductor and configured to generate a combined inductance.

10. The hybrid inductor device of claim 9, wherein the coil structure comprises a helical structure, a spiral structure, a single loop structure, a meandering structure, or a solenoid structure, or any combination thereof.

11. The hybrid inductor device of claim 9, wherein the first inductor comprises a conductive coil structure disposed in a ceramic body.

12. The hybrid inductor device of claim 9, wherein the conductive pattern is disposed on an insulating layer.

13. The hybrid inductor device of claim 12, wherein the second inductor comprises a plurality of insulating layers configured to generate an inductance, wherein the plurality of insulating layers are stacked.

14. A hybrid inductor device comprising:
a main board;
one or more electronic components mounted on the main board;
a first inductor mounted on the main board; and
a second inductor comprising a conductive pattern disposed on the main board and connected to the first inductor.

15. The hybrid inductor device of claim 14, wherein the one or more electronic components include at least one duplexer and at least one antenna switch, and the first inductor is disposed between the duplexer and the antenna switch, so as to be electrically connected to the duplexer and the antenna switch.

16. The hybrid inductor device of claim 15, wherein the first and second inductors are configured to impedance match the duplexer or the antenna switch.

17. The hybrid inductor device of claim 14, wherein the second inductor is disposed on the main board, below a mounting region of the one or more electronic components or the first inductor.
